(19) United States
(12) Patent Application Publication
(10) Pub. No.: US 2024/0178068 A1
(43) Pub. Date: May 30, 2024

(54) METHOD OF MANUFACTURING SEMICONDUCTOR DEVICE INCLUDING A FIN-TYPE ACTIVE REGION

(71) Applicant: SAMSUNG ELECTRONICS CO., LTD., Suwon-si (KR)

(72) Inventors: Seungju HWANG, Suwon-si (KR); Shigenobu Maeda, Suwon-si (KR); Myoungkyu PARK, Suwon-si (KR)

(21) Appl. No.: 18/383,940

(22) Filed: Oct. 26, 2023

(30) Foreign Application Priority Data
Nov. 24, 2022 (KR) 10-2022-0159493

(51) Int. Cl. H01L 21/8234; H01L 21/762; H01L 27/088

(52) U.S. Cl. CPC H01L 21/823431; H01L 21/76224; H01L 21/823481; H01L 27/0886

(57) ABSTRACT

A method of manufacturing a semiconductor device includes: forming a plurality of first mandrel patterns at a first mandrel pitch on a substrate; forming a first fin group and a first dummy fin group by patterning the substrate, wherein the first fin group is adjacent to the first dummy fin group in a first direction; and removing the first dummy fin group, wherein the first fin group includes a first fin and a second fin adjacent to each other and arranged at a first fin pitch in the first direction. The first dummy fin group includes a first dummy fin and a second dummy fin adjacent to each other and arranged at the first fin pitch in the first direction. The second fin and the first dummy fin, which is adjacent to the second fin, are arranged at a second fin pitch that is greater than the first fin pitch.

### CROSS-REFERENCE TO RELATED APPLICATION

This application claims priority under 35 U.S.C. § 119 to Korean Patent Application No. 10-2022-0159493, filed on Nov. 24, 2022, in the Korean Intellectual Property Office, the disclosure of which is incorporated by reference herein in its entirety.

### TECHNICAL FIELD

The present inventive concept relates to a method of manufacturing a semiconductor device, and more particularly, to a method of manufacturing a semiconductor device including a fin-type active region.

### DISCUSSION OF THE RELATED ART

With the desire for compact and multifunctionalized high-performance electronic products, the high capacity and high integration density of semiconductor devices are also desired. Accordingly, it is desirable to efficiently design interconnection structures to ensure desired functions and operating speed of a semiconductor device and to achieve high integration density.

### SUMMARY

According to an embodiment of the present inventive concept, a method of manufacturing a semiconductor device includes: forming a plurality of first mandrel patterns at a first mandrel pitch on a substrate; forming a plurality of first spacers on opposing side walls of each of the plurality of first mandrel patterns; forming a first fin group and a first dummy fin group by patterning the substrate by using the plurality of first spacers, wherein the first fin group is adjacent to the first dummy fin group in a first direction; and removing the first dummy fin group, wherein the first fin group includes a first fin and a second fin adjacent to each other and arranged at a first fin pitch in the first direction, wherein the first fin and the second fin extend in a second direction that crosses the first direction, the first dummy fin group includes a first dummy fin and a second dummy fin adjacent to each other and arranged at the first fin pitch in the first direction, wherein the first dummy fin and the second dummy fin extend in the second direction, and the second fin and the first dummy fin, which is adjacent to the second fin, are arranged at a second fin pitch that is greater than the first fin pitch.

According to an embodiment of the present inventive concept, a method of manufacturing a semiconductor device includes: forming a plurality of first mandrel patterns at a first mandrel pitch on a substrate; forming a first spacer on each of a plurality of side walls of each of the plurality of first mandrel patterns; and forming a first fin group and a second fin group by patterning the substrate by using the first spacer, wherein the first fin group is adjacent to the second fin group in a first direction, wherein the first fin group includes a first fin and a second fin adjacent to each other and arranged at a first fin pitch in the first direction, wherein the first fin and the second fin extend in a second direction that crosses the first direction, the second fin group includes a third fin and a fourth fin adjacent to each other and arranged at the first fin pitch in the first direction, wherein the third fin and the fourth fin extend in the second direction, and the second fin and the third fin, which is adjacent to the second fin, are arranged at a second fin pitch that is greater than three times the first fin pitch.

According to an embodiment of the present inventive concept, a method of manufacturing a semiconductor device includes: forming a plurality of first mandrel patterns at a first mandrel pitch in a first region of a substrate; forming a plurality of second mandrel patterns at the first mandrel pitch in a second region of the substrate; forming a plurality of first spacers on side walls of each of the plurality of first mandrel patterns, forming a plurality of second spacers on side walls of each of the plurality of second mandrel patterns; forming a plurality of first fin groups and a plurality of first dummy fin groups by patterning the first region of the substrate by using the plurality of first spacers, wherein the plurality of first fin groups are alternately arranged with the plurality of first dummy fin groups in a first direction; forming a plurality of second fin groups and a plurality of second dummy fin groups by patterning the second region of the substrate by using the plurality of second spacers, wherein the plurality of second fin groups are alternately arranged with the plurality of second dummy fin groups in a second direction; and removing the plurality of first dummy fin groups and the plurality of second dummy fin groups, wherein each of the plurality of first fin groups includes a first fin and a second fin adjacent to each other and arranged at a first fin pitch in the first direction, wherein the first fin and the second fin extend in a third direction that crosses the first direction. Each of the plurality of first dummy fin groups includes a first dummy fin and a second dummy fin adjacent to each other and arranged at the first fin pitch in the first direction, wherein the first dummy fin and the second dummy fin extending in the third direction. The second fin and the first dummy fin, which is adjacent to the second fin, are arranged at a second fin pitch that is greater than the first fin pitch. Each of the plurality of second fin groups includes a third fin and a fourth fin adjacent to each other and arranged at a third fin pitch in the second direction, wherein the third fin and the fourth fin extend in a fourth direction that crosses the second direction. Each of the plurality of second dummy fin groups includes a third dummy fin and a fourth dummy fin adjacent to each other and arranged at the third fin pitch in the second direction, wherein the third dummy fin and the fourth dummy fin extend in the fourth direction. The fourth fin and the third dummy fin, which is adjacent to the fourth fin, are arranged at the third fin pitch. The first fin pitch is less than the third fin pitch, and the second fin pitch is greater than the third fin pitch.

### BRIEF DESCRIPTION OF THE DRAWINGS

The above and other aspects of the present inventive concept will become more apparent by describing in detail embodiments thereof, with reference to the accompanying drawings, in which:

FIG. 1 is a conceptual diagram illustrating a method of manufacturing a semiconductor device, according to an embodiment of the present inventive concept;

FIGS. 2A, 2B, 2C, 2D, 2E, 2F and 2G are diagrams of intermediate stages in the method of FIG. 1, according to an embodiment of the present inventive concept;

FIGS. 3A, 3B, 3C and 3D are cross-sectional views of stages in a method of manufacturing a semiconductor device, according to an embodiment of the present inventive concept;

FIGS. 4A, 4B, 4C and 4D are cross-sectional views of stages in a method of manufacturing a semiconductor device, according to an embodiment of the present inventive concept;

FIG. 5 is a conceptual diagram illustrating a method of manufacturing a semiconductor device, according to an embodiment of the present inventive concept;

FIG. 6 is a conceptual diagram illustrating a method of manufacturing a semiconductor device, according to an embodiment of the present inventive concept;

FIGS. 7A, 7B, 7C, 7D, 7E, 7F and 7G are diagrams of intermediate stages in the method of FIG. 6, according to an embodiment of the present inventive concept;

FIG. 8 is a layout diagram illustrating some components of a semiconductor device manufactured by a method of manufacturing a semiconductor device, according to an embodiment of the present inventive concept;

FIGS. 9A and 9B show cross-sectional views respectively taken along line A1-A1 and line A2-A2 in FIG. 8, according to an embodiment of the present inventive concept;

FIG. 10 is a layout diagram illustrating some components of a semiconductor device manufactured by a method of manufacturing a semiconductor device, according to an embodiment of the present inventive concept;

FIGS. 11A, 11B, 11C and 11D are cross-sectional views taken along line B1-B1 in FIG. 10, according to an embodiment of the present inventive concept;

FIG. 12 is a cross-sectional view taken along line C1-C1 in FIG. 10, according to an embodiment of the present inventive concept; and

FIG. 13 is a layout diagram illustrating some components of a semiconductor device manufactured by a method of manufacturing a semiconductor device, according to an embodiment of the present inventive concept.

### DETAILED DESCRIPTION OF THE EMBODIMENTS

Hereinafter, embodiments of the present inventive concept are described with reference to the accompanying drawings. In the drawings, like reference characters denote like elements, and redundant descriptions thereof may be omitted or briefly discussed.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present inventive concept.

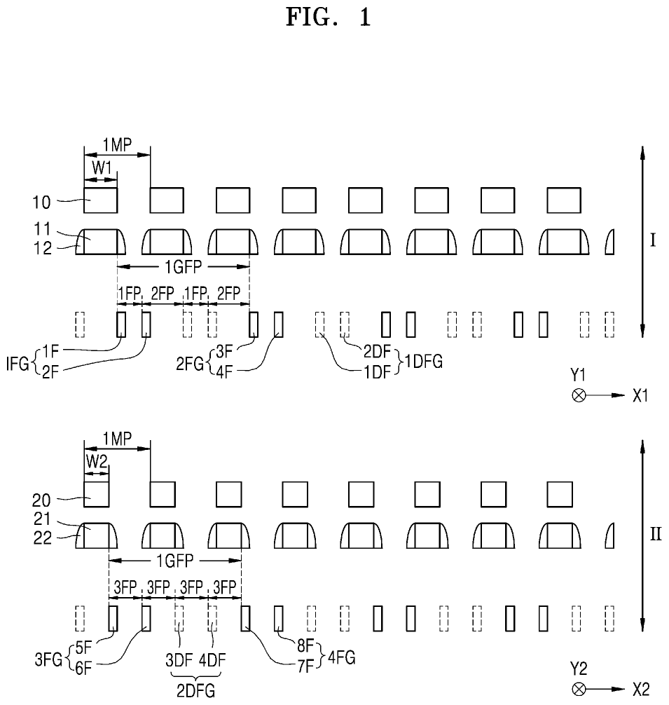

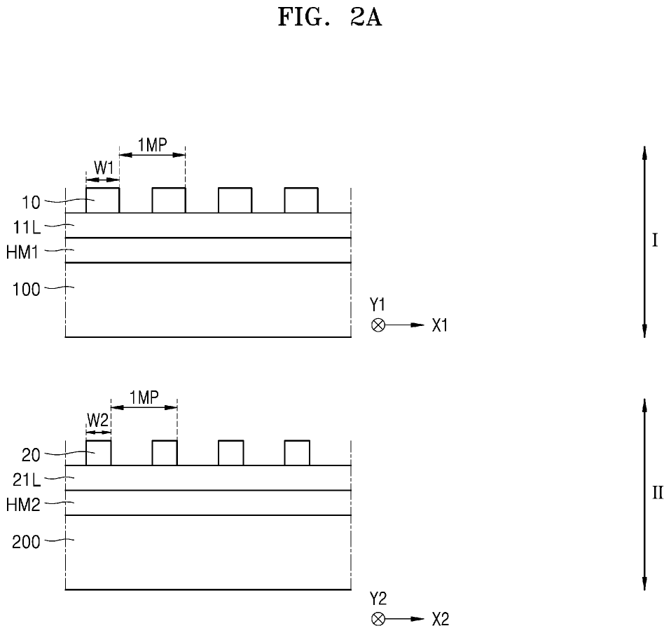

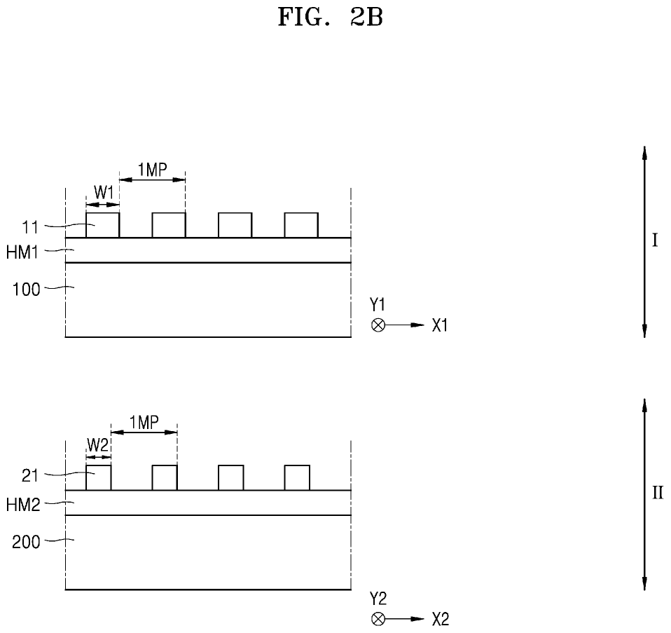

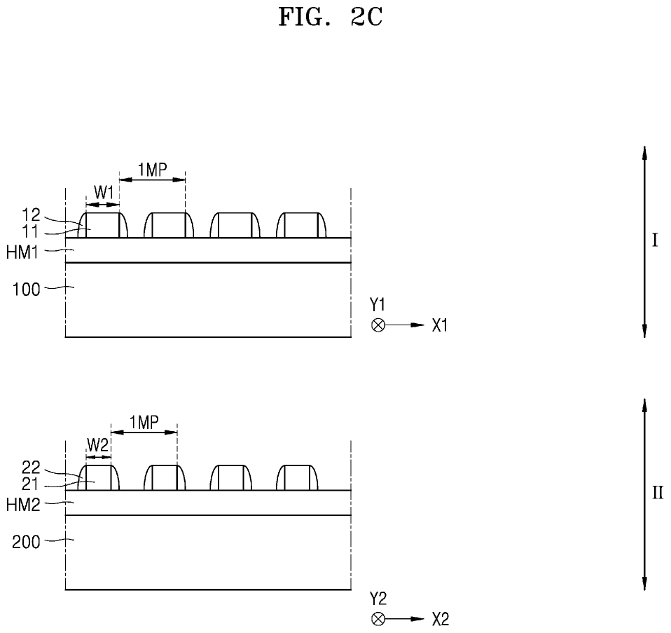

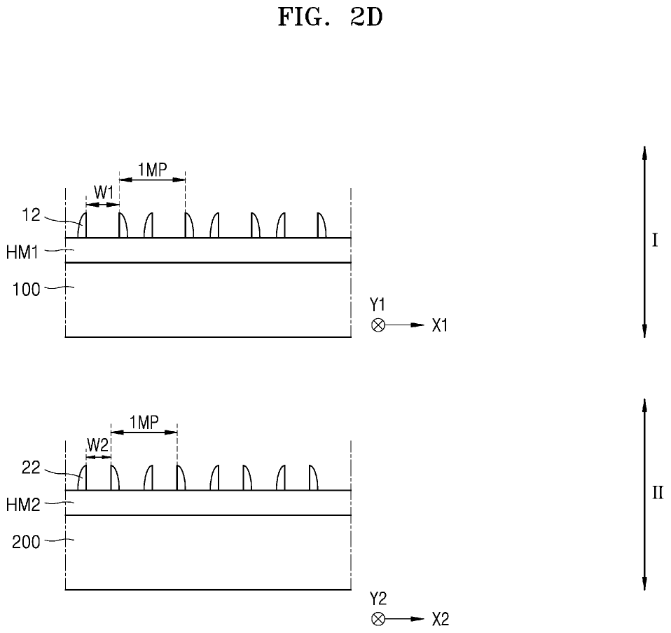

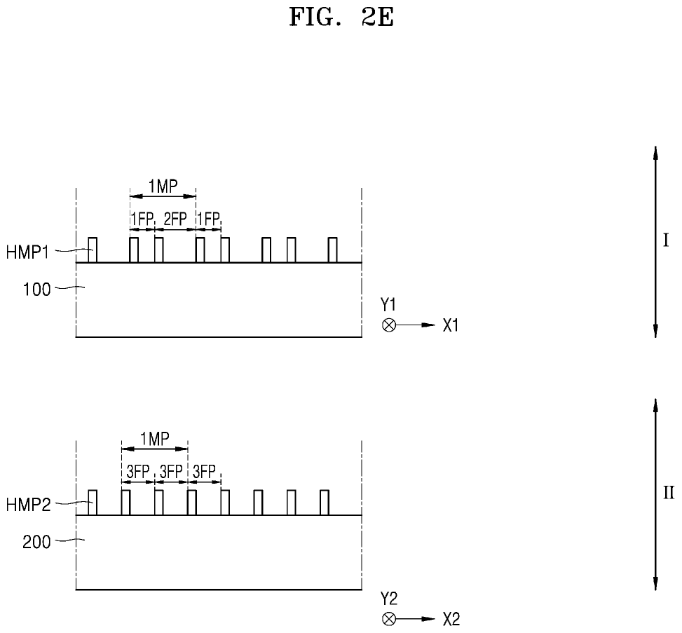

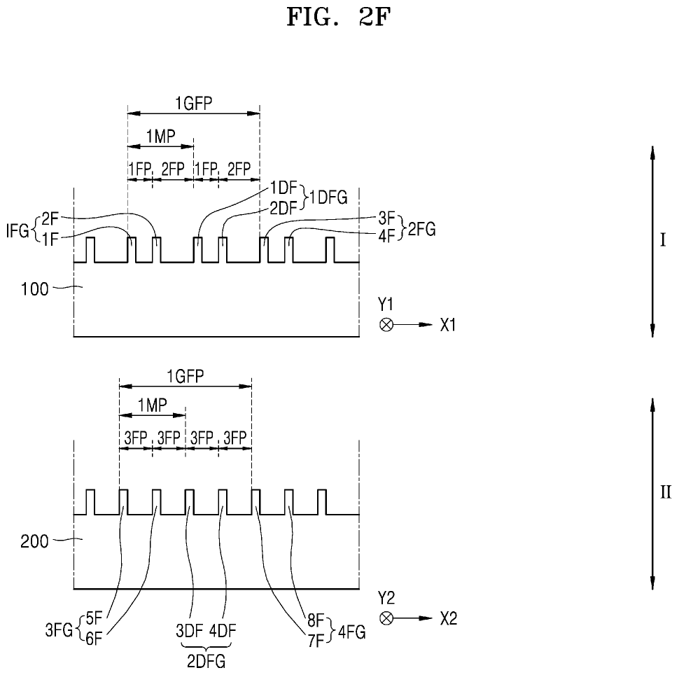

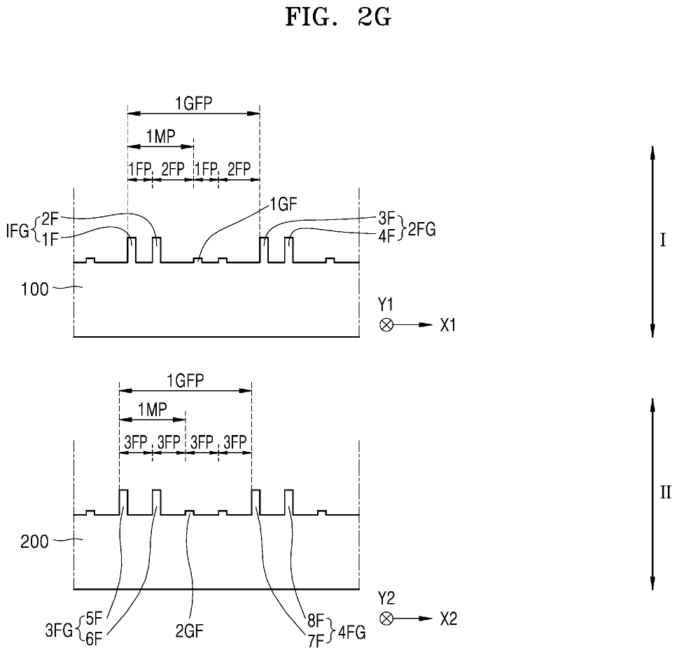

FIG. 1 is a conceptual diagram illustrating a method of manufacturing a semiconductor device, according to an embodiment of the present inventive concept. FIGS. 2A to 2G are diagrams of intermediate stages in the method of FIG. 1.

Referring to FIGS. 1 to 2G, the method of manufacturing a semiconductor device may include performing a self-aligned double patterning (SADP) process on a first region I and a second region II of a substrate by using a first mandrel pattern 11 and a second mandrel pattern 21, respectively, according to an embodiment of the present inventive concept.

For example, referring to FIGS. 1 and 2A, a substrate having the first region I and the second region II may be provided. The substrate may include a substrate 100 in the first region I and a substrate 200 in the second region II. The substrates 100 and 200 may include a semiconductor, such as Si or Ge, or a compound semiconductor, such as SiGe, SiC, GaAs, InAs, or InP. In addition, the substrates 100 and 200 may have a silicon-on-insulator (SOI) structure. For example, the substrates 100 and 200 may include an impurity-doped well or an impurity-doped structure. For example, the substrates 100 and 200 may have a different material from each other.

A first hardmask film HM1 and a first sacrificial film 11L may be sequentially formed on the substrate 100 in the first region I, and first photoresist patterns 10 having a first mandrel pitch 1MP may be formed. The first photoresist patterns 10 may be arranged in a first direction X1 in the first region I and may extend in a second direction Y1 that crosses the first direction X1.

A second hardmask film HM2 and a second sacrificial film 21L may be sequentially formed on the substrate 200 in the second region II, and second photoresist patterns 20 having the first mandrel pitch 1MP may be formed. The second photoresist patterns 20 may be arranged in a third direction X2 in the second region II and may extend in a fourth direction Y2 that crosses the third direction X2.

Although it is illustrated for convenience of description that the first direction X1 is the same as the third direction X2, the present inventive concept is not limited thereto. For example, the first direction X1 may be different from the third direction X2.

In some embodiments of the present inventive concept, each of the first hardmask film HM1 and the second hardmask film HM2 may include a plurality of layers. For example, each of the layers may include at least one of a silicon-containing material, such as silicon oxide, silicon oxynitride, silicon nitride, tetra-ethyl-ortho-silicate (TEOS), or polycrystalline silicon, a carbon-containing material, such as an amorphous carbon layer (ACL) or a spin-on hardmask (SOH), and a metal, but the present inventive concept is not limited thereto.

In some embodiments of the present inventive concept, the first sacrificial film 11L and the second sacrificial film 21L may include, for example, polycrystalline silicon, an ACL, or an SOH, but the present inventive concept is not limited thereto.

The first photoresist patterns 10 and the second photoresist patterns 20 may be arranged at the same first mandrel pitch 1MP on the substrate 100 in the first region I and the substrate 200 in the second region II, respectively. In some embodiments of the present inventive concept, the first mandrel pitch 1MP may be at least about 76 nm.

In some embodiments of the present inventive concept, a width W1 in the first direction X1 of each first photoresist pattern 10 may be greater than a width W2 in the third direction X2 of each second photoresist pattern 20. For example, a distance between two adjacent first photoresist patterns 10 may be less than a distance between two adjacent second photoresist patterns 20.

Referring to FIGS. 1 and 2B, a first mandrel pattern 11 may be formed by transferring a first photoresist pattern 10, and a second mandrel pattern 21 may be formed by transferring a second photoresist pattern 20. For example, the first mandrel pattern 11 may be formed by etching the first sacrificial film 11L by using the first photoresist pattern 10 on the substrate 100 in the first region I as a mask. The second mandrel pattern 21 may be formed by etching the second sacrificial film 21L by using the second photoresist pattern 20 on the substrate 200 in the second region II as a mask.

In some embodiments of the present inventive concept, first mandrel patterns 11 may be arranged at the first mandrel pitch 1MP in the first direction X1 in the first region I and may extend in the second direction Y1. In some embodiments of the present inventive concept, second mandrel patterns 21 may be arranged at the first mandrel pitch 1MP in the third direction X2 in the second region II and may extend in the fourth direction Y2.

Referring to FIGS. 1 and 2C, a first spacer 12 may be formed on both side walls of a first mandrel pattern 11 on the substrate 100 in the first region I, and a second spacer 22 may be formed on both side walls of a second mandrel pattern 21 on the substrate 200 in the second region II.

In some embodiments of the present inventive concept, the forming of the first spacer 12 may include forming a first spacer film, which extends along the side walls and top surface of the first mandrel pattern 11 and the top surface of the first hardmask film HM1, on the substrate 100 in the first region I and performing anisotropic etching on the first spacer film. Accordingly, the first spacer 12 may be formed on each of both side walls of the first mandrel pattern 11.

In some embodiments of the present inventive concept, the forming of the second spacer 22 may include forming a second spacer film, which extends along the side walls and top surface of the second mandrel pattern 21 and the top surface of the second hardmask film HM2, on the substrate 200 in the second region II and performing anisotropic etching on the second spacer film. Accordingly, the second spacer 22 may be formed on each of both side walls of the second mandrel pattern 21.

In some embodiments of the present inventive concept, the first spacer film and the second spacer film may be formed by atomic layer deposition (ALD), chemical vapor deposition (CVD), or the like.

In some embodiments of the present inventive concept, the first spacer 12 and the second spacer 22 may include at least one of silicon oxide, silicon nitride, silicon oxynitride, and a combination thereof, but the present inventive concept is not limited thereto.

In some embodiments of the present inventive concept, a width in the first direction X1 of the first spacer 12 may be adjusted to form a first fin group 1FG and a first dummy fin group 1DFG. Similarly, a width in the third direction X2 of the second spacer 22 may be adjusted to form a third fin group 3FG and a second dummy fin group 2DFG. For example, the width in the first direction X1 of the first spacer 12 may be the same as the width in the third direction X2 of the second spacer 22.

Referring to FIGS. 1 and 2D, the first mandrel pattern 11 on the substrate 100 in the first region I and the second mandrel pattern 21 on the substrate 200 in the second region II may be removed. The first spacer 12 may include a material having an etch selectivity with respect to the first mandrel pattern 11 and thus might not be removed when the first mandrel pattern 11 is removed. The second spacer 22 may include a material having an etch selectivity with respect to the second mandrel pattern 21 and thus might not be removed when the second mandrel pattern 21 is removed.

Referring to FIGS. 1 and 2E, a first hardmask pattern HMP1 and a second hardmask pattern HMP2 may be formed by using the first spacer 12 and the second spacer 22 as etch masks.

For example, the first hardmask film HM1 may be etched by using the first spacer 12 as an etch mask on the substrate 100 in the first region I. In other words, the first hardmask pattern HMP1 may result from a transfer of the first spacer 12. Subsequently, the first spacer 12 may be removed.

For example, the second hardmask film HM2 may be etched by using the second spacer 22 as an etch mask on the substrate 200 in the second region II. In other words, the second hardmask pattern HMP2 may result from a transfer of the second spacer 22. Subsequently, the second spacer 22 may be removed.

First hardmask patterns HMP1 on the substrate 100 in the first region I may include two adjacent patterns arranged at a first fin pitch 1FP and/or two adjacent patterns arranged at a second fin pitch 2FP.

Second hardmask patterns HMP2 on the substrate 200 in the second region II may include two adjacent patterns arranged at a third fin pitch 3FP.

Referring to FIGS. 1 and 2F, the substrates 100 and 200 may be patterned by using the first hardmask patterns HMP1 and the second hardmask patterns HMP2 as etch masks. Accordingly, a plurality of fins, e.g., first to eighth fins 1F to 8F, may be formed on the substrates 100 and 200.

For example, a first fin group 1FG, a first dummy fin group 1DFG, and a second fin group 2FG, which are adjacent to each other in the first direction X1, may be formed by patterning the substrate 100 in the first region I by using the first hardmask patterns HMP1 as etch masks.

The first fin group 1FG may include the first fin 1F and the second fin 2F, which are arranged at the first fin pitch 1FP to be adjacent to each other in the first direction X1 and extend in the second direction Y1. The first dummy fin group 1DFG may include a first dummy fin 1DF and a second dummy fin 2DF, which are arranged at the first fin pitch 1FP to be adjacent to each other in the first direction X1 and extend in the second direction Y1. The second fin group 2FG may include the third fin 3F and the fourth fin 4F, which are arranged at the first fin pitch 1FP to be adjacent to each other in the first direction X1 and extend in the second direction Y1.

In some embodiments of the present inventive concept, the first fin group 1FG may be separated from the second fin group 2FG by the first dummy fin group 1DFG therebetween. In other words, the first fin group 1FG, the first dummy fin group 1DFG, and the second fin group 2FG may be sequentially arranged to be adjacent to each other.

In some embodiments of the present inventive concept, the second fin 2F and the first dummy fin 1DF adjacent to the second fin 2F may be arranged at the second fin pitch 2FP that is greater than the first fin pitch 1FP. In some embodiments of the present inventive concept, the second dummy fin 2DF and the third fin 3F adjacent to the second dummy fin 2DF may be arranged at the second fin pitch 2FP.

In other words, on the substrate 100 in the first region I, a plurality of adjacent fins in a fin group may be arranged at the first fin pitch 1FP, and a plurality of adjacent dummy fins in a dummy fin group may be arranged at the first fin pitch 1FP. For example, the first fin 1F and the second fin 2F adjacent to the first fin 1F in the first fin group 1FG may be arranged at the first fin pitch 1FP, and the third fin 3F and the fourth fin 4F adjacent to the third fin 3F in the second fin group 2FG may be arranged at the first fin pitch 1FP Further, the first dummy fin 1DF and the second dummy fin 2DF adjacent to the first dummy fin 1DF in the first dummy fin group 1DFG may be arranged at the first fin pitch 1FP.

In other words, a fin and a dummy fin adjacent thereto may be arranged at the second fin pitch 2FP on the substrate 100 in the first region I. For example, the second fin 2F and the first dummy fin 1DF adjacent thereto may be arranged at the second fin pitch 2FP, and the third fin 3F and the second dummy fin 2DF adjacent thereto may be arranged at the second fin pitch 2FP.

In other words, on the substrate 100 in the first region I, a pitch (e.g., the second fin pitch 2FP) between a fin and a dummy fin adjacent thereto may be greater than each of a pitch (e.g., the first fin pitch 1FP) between fins and a pitch (e.g., the first fin pitch 1FP) between dummy fins.

For example, the second fin pitch 2FP may be greater than the first fin pitch 1FP and less than twice the first fin pitch 1FP. For example, the second fin pitch 2FP may be greater than the first fin pitch 1FP and less than about 1.7 times the first fin pitch 1FP.

In some embodiments of the present inventive concept, the first fin group 1FG and the first dummy fin group 1DFG may be arranged at the first mandrel pitch 1MP. In other words, the first fin 1F and the first dummy fin 1DF may be arranged at the first mandrel pitch 1MP. The second fin 2F and the second dummy fin 2DF may be arranged at the first mandrel pitch 1MP.

In some embodiments of the present inventive concept, the first dummy fin group 1DFG and the second fin group 2FG may be arranged at the first mandrel pitch 1MP. In other words, the first dummy fin 1DF and the third fin 3F may be arranged at the first mandrel pitch 1MP. The second dummy fin 2DF and the fourth fin 4F may be arranged at the first mandrel pitch 1MP.

In other words, the first mandrel pitch 1MP may be equal to the sum of the first fin pitch 1FP and the second fin pitch 2FP. In some embodiments of the present inventive concept, the first mandrel pitch 1MP may be greater than twice the first fin pitch 1FP. In some embodiments of the present inventive concept, the first mandrel pitch 1MP may be less than twice the second fin pitch 2FP. For example, the first mandrel pitch 1MP may be greater than twice the first fin pitch 1FP and less than about three times the first fin pitch 1FP. For example, the first mandrel pitch 1MP may be greater than about 1.5 times the second fin pitch 2FP and less than about twice the first fin pitch 1FP.

In other words, the first fin pitch 1FP may be less than about half the first mandrel pitch 1MP. For example, the first fin pitch 1FP may be less than about 38 nm. For example, the first fin pitch 1FP may be at least about 26 nm and less than about 38 nm. For example, the first fin pitch 1FP may be at least about 30 nm and less than about 38 nm. For example, the first fin pitch 1FP may be at least about 34 nm and less than about 38 nm.

In some embodiments of the present inventive concept, the first fin group 1FG and the second fin group 2FG may be arranged at a first group fin pitch 1GFP. In other words, the first fin 1F and the third fin 3F may be arranged at the first group fin pitch 1GFP. The second fin 2F and the fourth fin 4F may be arranged at the first group fin pitch 1GFP.

In other words, the first group fin pitch 1GFP may be equal to about twice the first mandrel pitch 1MP. In some embodiments of the present inventive concept, the first group fin pitch 1GFP may be greater than about four times the first fin pitch 1FP. In some embodiments of the present inventive concept, the first group fin pitch 1GFP may be less than about four times the second fin pitch 2FP. In some embodiments of the present inventive concept, the first group fin pitch 1GFP may be greater than about four times the first fin pitch 1FP and less than about six times the first fin pitch 1FP. In some embodiments of the present inventive concept, the first group fin pitch 1GFP may be greater than about three times the second fin pitch 2FP and less than about four times the second fin pitch 2FP.

A third fin group 3FG, a second dummy fin group 2DFG, and a fourth fin group 4FG, which are adjacent to each other in the third direction X2, may be formed by patterning the substrate 200 in the second region II by using the second hardmask patterns HMP2 as etch masks.

The third fin group 3FG may include the fifth fin 5F and the sixth fin 6F, which are arranged at the third fin pitch 3FP to be adjacent to each other in the third direction X2 and extend in the fourth direction Y2. The second dummy fin group 2DFG may include a third dummy fin 3DF and a fourth dummy fin 4DF, which are arranged at the third fin pitch 3FP to be adjacent to each other in the third direction X2 and extend in the fourth direction Y2. The fourth fin group 4FG may include the seventh fin 7F and the eighth fin 8F, which are arranged at the third fin pitch 3FP to be adjacent to each other in the third direction X2 and extend in the fourth direction Y2.

In some embodiments of the present inventive concept, the third fin group 3FG may be separated from the fourth fin group 4FG by the second dummy fin group 2DFG therebetween. In other words, the third fin group 3FG, the second dummy fin group 2DFG, and the fourth fin group 4FG may be sequentially arranged to be adjacent to each other.

In some embodiments of the present inventive concept, the sixth fin 6F and the third dummy fin 3DF adjacent to the sixth fin 6F may be arranged at the third fin pitch 3FP. In some embodiments of the present inventive concept, the fourth dummy fin 4DF and the seventh fin 7F adjacent to the fourth dummy fin 4DF may be arranged at the third fin pitch 3FP.

In other words, on the substrate 200 in the second region II, a plurality of adjacent fins in a fin group may be arranged at the third fin pitch 3FP, and a plurality of adjacent dummy fins in a dummy fin group may be arranged at the third fin pitch 3FP. For example, the fifth fin 5F and the sixth fin 6F adjacent to the fifth fin 5F in the third fin group 3FG may be arranged at the third fin pitch 3FP, the seventh fin 7F and the eighth fin 8F adjacent to the seventh fin 7F in the fourth fin group 4FG may be arranged at the third fin pitch 3FP, and the third dummy fin 3DF and the fourth dummy fin 4DF adjacent to the third dummy fin 3DF in the second dummy fin group 2DFG may be arranged at the third fin pitch 3FP.

In other words, a fin and a dummy fin adjacent thereto may be arranged at the third fin pitch 3FP on the substrate 200 in the second region II. For example, the sixth fin 6F and the third dummy fin 3DF adjacent thereto may be arranged at the third fin pitch 3FP, and the seventh fin 7F and the fourth dummy fin 4DF adjacent thereto may be arranged at the third fin pitch 3FP.

In other words, on the substrate 200 in the second region II, a plurality of fins (5F to 8F) and a plurality of dummy fins (3DF and 4DF) may be arranged at the third fin pitch 3FP.

In some embodiments of the present inventive concept, the third fin group 3FG and the second dummy fin group 2DFG may be arranged at the first mandrel pitch 1MP. In other words, the fifth fin 5F and the third dummy fin 3DF may be arranged at the first mandrel pitch 1MP. The sixth fin 6F and the fourth dummy fin 4DF may be arranged at the first mandrel pitch 1MP.

In some embodiments of the present inventive concept, the second dummy fin group 2DFG and the fourth fin group 4FG may be arranged at the first mandrel pitch 1MP. In other words, the third dummy fin 3DF and the seventh fin 7F may be arranged at the first mandrel pitch 1MP. The fourth dummy fin 4DF and the eighth fin 8F may be arranged at the first mandrel pitch 1MP.

In other words, the first mandrel pitch 1MP may be equal to about twice the third fin pitch 3FP. In other words, about twice the third fin pitch 3FP may be equal to the sum of the first fin pitch 1FP and the second fin pitch 2FP.

In some embodiments of the present inventive concept, the third fin pitch 3FP may be greater than the first fin pitch 1FP and less than the second fin pitch 2FP. For example, the third fin pitch 3FP may be greater than the first fin pitch 1FP and less than about 3/2 of the first fin pitch 1FP. For example, the third fin pitch 3FP may be greater than about ¾ of the second fin pitch 2FP and less than the second fin pitch 2FP.

In other words, the first fin pitch 1FP may be less than the third fin pitch 3FP, and the second fin pitch 2FP may be greater than the third fin pitch 3FP. For example, the first fin pitch 1FP may be greater than about ⅔ of the third fin pitch 3FP and less than the third fin pitch 3FP. For example, the second fin pitch 2FP may be greater than the third fin pitch 3FP and less than about 4/3 of the third fin pitch 3FP.

In some embodiments of the present inventive concept, the third fin group 3FG and the fourth fin group 4FG may be arranged at the first group fin pitch. In other words, the fifth fin 5F and the seventh fin 7F may be arranged at the first group fin pitch 1GFP. The sixth fin 6F and the eighth fin 8F may be arranged at the first group fin pitch 1GFP. In other words, the first group fin pitch 1GFP may be equal to about four times the third fin pitch 3FP.

In other words, the first group fin pitch 1GFP may be greater than about four times the first fin pitch 1FP and less than about four times the second fin pitch 2FP.

Referring to FIGS. 1 and 2G, the first dummy fin group 1DFG and the second dummy fin group 2DFG may be removed. For example, first ghost fins 1GF may be formed by removing the first dummy fin group 1DFG from the substrate 100 in the first region I. The first ghost fins 1GF may be trace left after the removal of the first dummy fin 1DF and the second dummy fin 2DF. The first ghost fins 1GF may protrude from the substrate 100 and may be lower than the first to fourth fins 1F to 4F. For example, the first ghost fins 1GF may have a height lower than each of those of the first to fourth fins 1F to 4F. Second ghost fins 2GF may be formed by removing the second dummy fin group 2DFG from the substrate 200 in the second region II. The second ghost fins 2GF may be trace left after the removal of the third dummy fin 3DF and the fourth dummy fin 4DF. The second ghost fins 2GF may protrude from the substrate 200 and may be lower than the fifth to eighth fins 5F to 8F. For example, the second ghost fins 2GF may have a height lower than each of those of the fifth to eighth fins 5F to 8F.

For example, the first dummy fin group 1DFG and the second dummy fin group 2DFG may be removed by a fin-cut process.

Although it is illustrated that the first mandrel patterns 11 having the first mandrel pitch 1MP are provided in the first region I in FIG. 1 and the second mandrel patterns 21 having the first mandrel pitch 1MP are provided in the second region II in FIG. 1, this is just for convenience of comparison. The first mandrel patterns 11 may be arranged at a different mandrel pitch than the second mandrel patterns 21.

A semiconductor device including the first fin 1F and the second fin 2F, which are arranged at the first fin pitch 1FP that is less than the third fin pitch 3FP, may be manufactured by the method illustrated in FIGS. 1 to 2G. For example, a method of manufacturing a semiconductor device having increased integration density may be provided where the third fin pitch 3FP is a minimum fin pitch at which a plurality of fins and dummy fins may be uniformly arranged, by inducing non-uniform pitches (the first fin pitch 1FP and the second fin pitch 2FP) and forming a plurality of fins arranged at the first fin pitch 1FP.

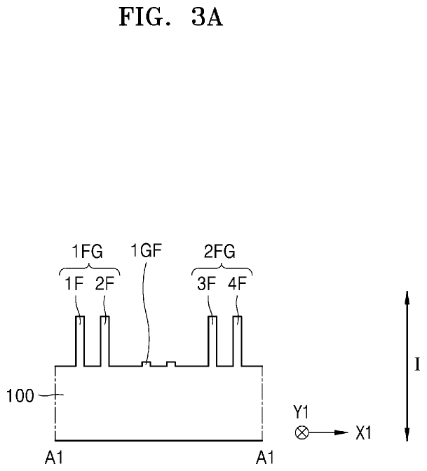

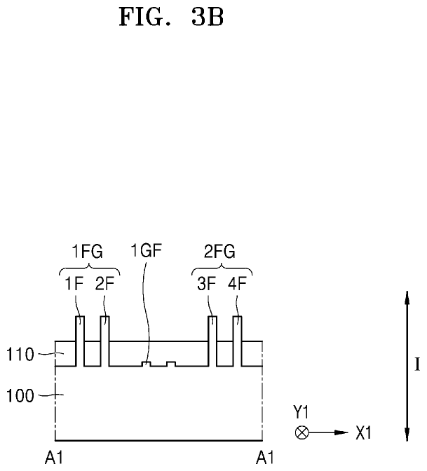

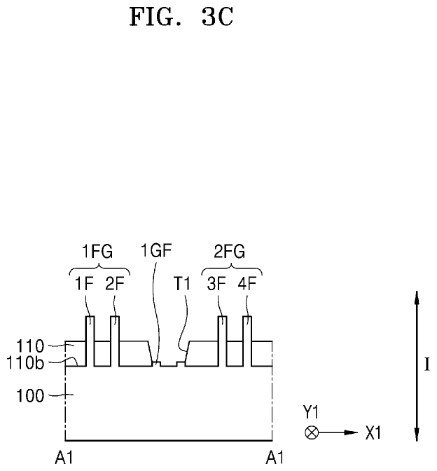

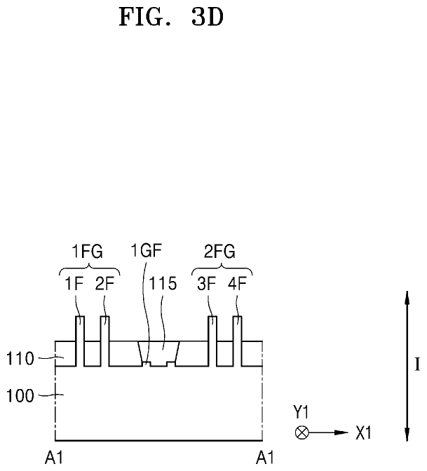

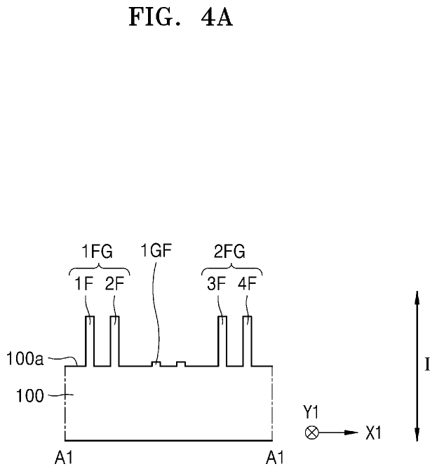

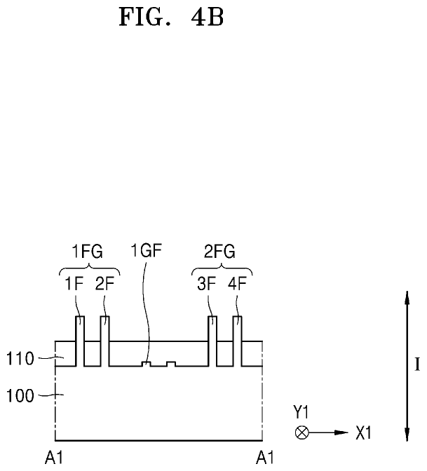

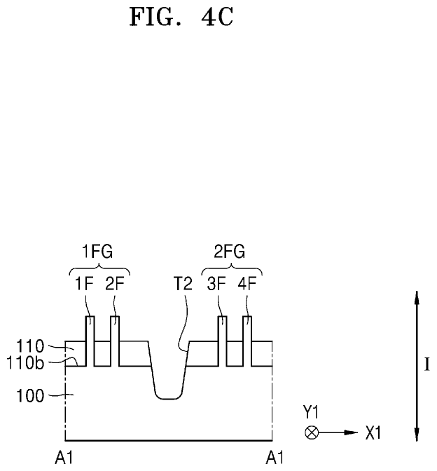

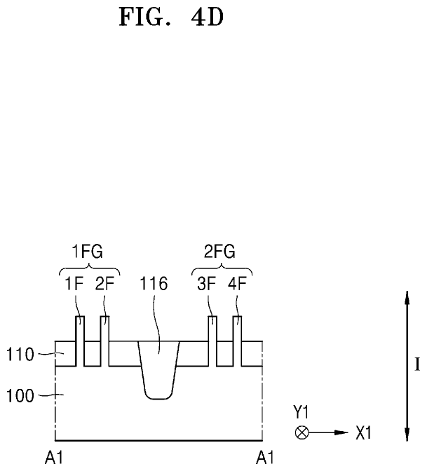

FIGS. 3A to 3D are cross-sectional views of stages in a method of manufacturing a semiconductor device, according to embodiments of the present inventive concept. In detail, FIGS. 3A to 3D show stages following the method illustrated in FIGS. 1 to 2G. FIGS. 4A to 4D are cross-sectional views of stages in a method of manufacturing a semiconductor device, according to embodiments of the present inventive concept. In detail, FIGS. 4A to 4D show stages following the method illustrated in FIGS. 1 to 2G.

Referring to FIGS. 3A to 3D, a first field insulating film 110 and a second field insulating film 115 may be formed on the substrate 100 in the first region I.

As shown in FIG. 3B, the first field insulating film 110 may be formed between the first fin group 1FG and the second fin group 2FG. The first field insulating film 110 may cover the first ghost fins 1GF that are between the first fin group 1FG and the second fin group 2FG. The first field insulating film 110 may at least partially surround a lower portion of the first fin group 1FG and a lower portion of the second fin group 2FG. The first field insulating film 110 may be among the first to fourth fins 1F to 4F and may at least partially surround respective lower portions of the first to fourth fins 1F to 4F.

As shown in FIG. 3C, a first trench T1 may be formed by etching a portion of the first field insulating film 110 between the first fin group 1FG and the second fin group 2FG. The vertical level of the bottom surface of the first trench T1 may be the same as the vertical level of a bottom surface 110b of the first field insulating film 110.

As shown in FIG. 3D, the second field insulating film 115 may be formed to fill the first trench T1. For example, an upper surface of the second field insulating film 115 may be substantially coplanar with an upper surface of the first field insulating film 110.

Referring to FIGS. 4A to 4D, the first field insulating film 110 and a second field insulating film 115 may be formed on the substrate 100 in the first region I.

As shown in FIG. 4B, the first field insulating film 110 may be formed between the first fin group 1FG and the second fin group 2FG. The forming of the first field insulating film 110 in FIG. 4B may be substantially the same as the forming of the first field insulating film 110 in FIG. 3B.

As shown in FIG. 4C, a second trench T2 may be formed by etching a portion of the first field insulating film 110, which is between the first fin group 1FG and the second fin group 2FG, and a portion of the substrate 100. The vertical level of the bottom surface of the second trench T2 may be lower than the vertical level of the bottom surface 110b of the first field insulating film 110.

As shown in FIG. 4D, the second field insulating film 116 may be formed to fill the second trench T2. For example, an upper surface of the second field insulating film 116 may be substantially coplanar with the upper surface of the first field insulating film 110.

In FIGS. 3A to 3D, each of the first field insulating film 110 and the second field insulating film 115 may include silicon oxide. In some embodiments of the present inventive concept, the first field insulating film 110 may have a different stress state than the second field insulating film 115. Similarly, in FIGS. 4A to 4D, each of the first field insulating film 110 and the second field insulating film 116 may include silicon oxide. In some embodiments of the present inventive concept, the first field insulating film 110 may have a different stress state than the second field insulating film 116.

For example, the first field insulating film 110 may have compressive stress, and the second field insulating films 115 and 116 may have tensile stress. In addition, the first field insulating film 110 may have tensile stress, and the second field insulating films 115 and 116 may have compressive stress. Because the first field insulating film 110 has a different stress state than the second field insulating film 115 or 116, the performance of a semiconductor device may increase. For example, because the first field insulating film 110 has a different stress state than the second field insulating film 115 or 116, the performance of a semiconductor device including a p-channel metal-oxide semiconductor (PMOS) and/or an n-channel MOS (NMOS) may increase.

In some embodiments of the present inventive concept, the first field insulating film 110 may have a different stress state than the second field insulating film 115 or 116 because of a difference in formation conditions therebetween. For example, elements of the first field insulating film 110 may have a different bond relationship than elements of the second field insulating film 115 or 116 because of a difference in formation temperature, time, or the like, and accordingly, the first field insulating film 110 may have a different stress state than the second field insulating film 115 or 116.

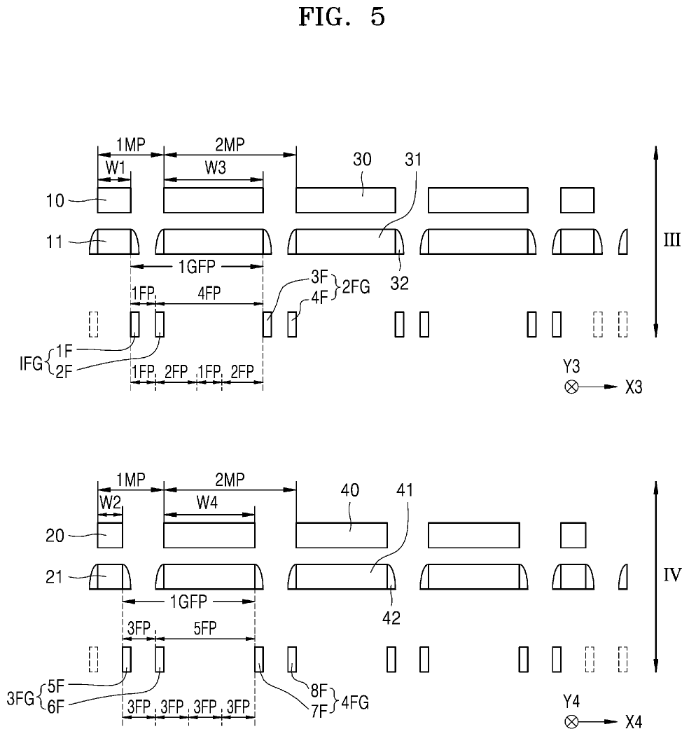

FIG. 5 is a conceptual diagram illustrating a method of manufacturing a semiconductor device, according to an embodiment of the present inventive concept.

Referring to FIG. 5, a substrate having a third region III and a fourth region IV may be provided. Differences between FIG. 1 and FIG. 5 are mainly described below and redundant descriptions may be omitted or briefly discussed.

Third mandrel patterns 31 having a second mandrel pitch 2MP that is greater than the first mandrel pitch 1MP may be provided in the third region III. For example, the second mandrel pitch 2MP may be about twice the first mandrel pitch 1MP. A width W3 of a third mandrel pattern 31 may be greater than the width W1 of a first mandrel pattern 11. The width W3 of the third mandrel pattern 31 may be selected such that the second fin 2F and the third fin 3F may be arranged at a fourth fin pitch 4FP.

A third spacer 32 may be formed on each of both side walls of the third mandrel pattern 31. Subsequently, the third mandrel pattern 31 may be removed, and the third spacer 32 may be transferred such that the substrate is patterned. Accordingly, the first fin group 1FG, which includes the first fin 1F and the second fin 2F, and the second fin group 2FG, which includes the third fin 3F and the fourth fin 4F, may be formed on the substrate. Unlike the method illustrated in FIGS. 1 to 2G, the first dummy fin group 1DFG might not be formed.

In some embodiments of the present inventive concept, the first fin 1F and the second fin 2F may be arranged at the first fin pitch 1FP in a fifth direction X3, and the third fin 3F and the fourth fin 4F may be arranged at the first fin pitch 1FP in the fifth direction X3. The second fin 2F and the third fin 3F, which are adjacent to each other, may be arranged at the fourth fin pitch 4FP in the fifth direction X3. The first to fourth fins 1F to 4F may extend in a sixth direction Y3. The fourth fin pitch 4FP may be the sum of the first fin pitch 1FP and about twice the second fin pitch 2FP, which has been described with reference to FIGS. 1 to 2G. In other words, the fourth fin pitch 4FP may be greater than about three times the first fin pitch 1FP. In other words, the fourth fin pitch 4FP may be less than about three times the second fin pitch 2FP. In other words, the fourth fin pitch 4FP may be less than about five times the first fin pitch 1FP.

In some embodiments of the present inventive concept, the first fin group 1FG and the second fin group 2FG may be arranged at the first group fin pitch 1GFP. In other words, the first fin 1F and the third fin 3F may be arranged at the first group fin pitch 1GFP. The second fin 2F and the fourth fin 4F may be arranged at the first group fin pitch 1GFP.

Fourth mandrel patterns 41 having the second mandrel pitch 2MP that is greater than the first mandrel pitch 1MP may be provided in the fourth region IV. A width W4 of a fourth mandrel pattern 41 may be greater than the width W2 of a second mandrel pattern 21. The width W4 of the fourth mandrel pattern 41 may be selected such that the sixth fin 6F and the seventh fin 7F may be arranged at a fifth fin pitch 5FP.

A fourth spacer 42 may be formed on each of both side walls of the fourth mandrel pattern 41. Subsequently, the fourth mandrel pattern 41 may be removed, and the fourth spacer 42 may be transferred such that the substrate is patterned. Accordingly, the third fin group 3FG, which includes the fifth fin 5F and the sixth fin 6F, and the fourth fin group 4FG, which includes the seventh fin 7F and the eighth fin 8F, may be formed on the substrate. Unlike the method illustrated in FIGS. 1 to 2G, the second dummy fin group 2DFG might not be formed.

In some embodiments of the present inventive concept, the fifth fin 5F and the sixth fin 6F may be arranged at the third fin pitch 3FP in a seventh direction X4, and the seventh fin 7F and the eighth fin 8F may be arranged at the third fin pitch 3FP in the seventh direction X4. The sixth fin 6F and the seventh fin 7F, which are adjacent to each other, may be arranged at the fifth fin pitch 5FP in the seventh direction X4. The fifth to eighth fins 5F to 8F may extend in an eighth direction Y4. The fifth fin pitch 5FP may be about three times the third fin pitch 3FP.

Although it is illustrated that the third mandrel patterns 31 having the second mandrel pitch 2MP are provided in the third region III in FIG. 5 and the fourth mandrel patterns 41 having the second mandrel pitch 2MP are provided in the fourth region IV in FIG. 5, this is just for convenience of comparison. The third mandrel patterns 31 may be arranged at a different mandrel pitch than that of the fourth mandrel patterns 41.

Although the fourth fin pitch 4FP that is equal to the sum of the first fin pitch 1FP and about twice the second fin pitch 2FP is illustrated in the third region III in FIG. 5, this is just for convenience of comparison. The second fin 2F and the third fin 3F, which are adjacent to each other, may be arranged at the fourth fin pitch 4FP that is different from the fourth fin pitch 4FP in FIG. 5.

Although the fifth fin pitch 5FP that is about three times the third fin pitch 3FP is illustrated in the fourth region IV in FIG. 5, this is just for convenience of comparison. The sixth fin 6F and the seventh fin 7F, which are adjacent to each other, may be arranged at the fifth fin pitch 5FP that is different from the fifth fin pitch 5FP in FIG. 5.

A semiconductor device including the first fin 1F and the second fin 2F, which are arranged at the first fin pitch 1FP that is less than the third fin pitch 3FP, may be manufactured by the method illustrated in FIG. 5.

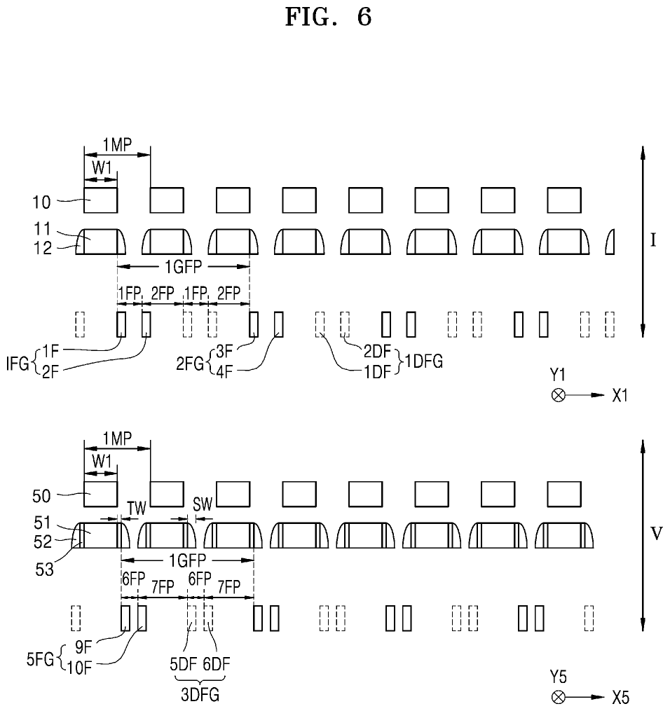

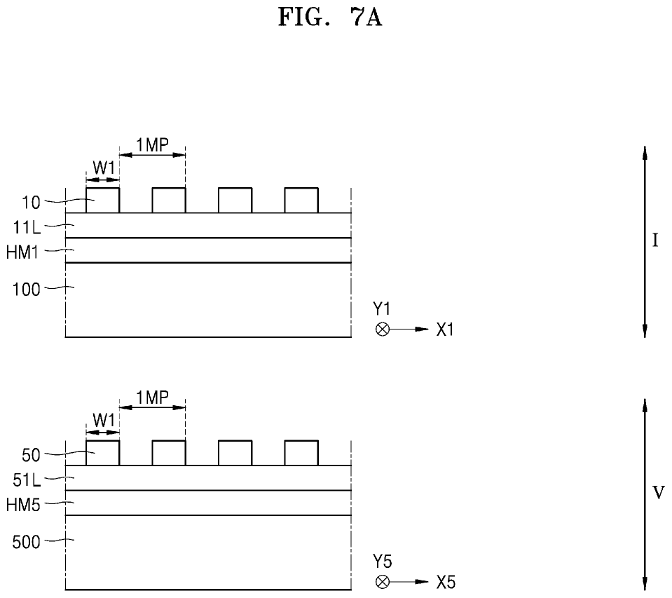

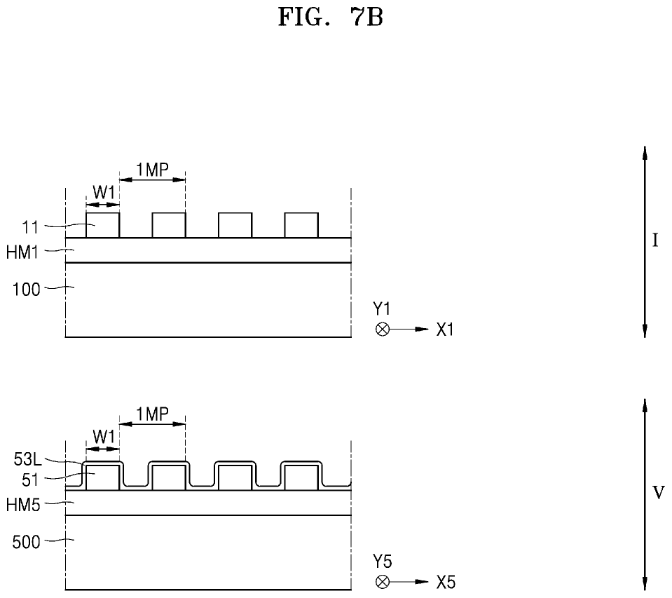

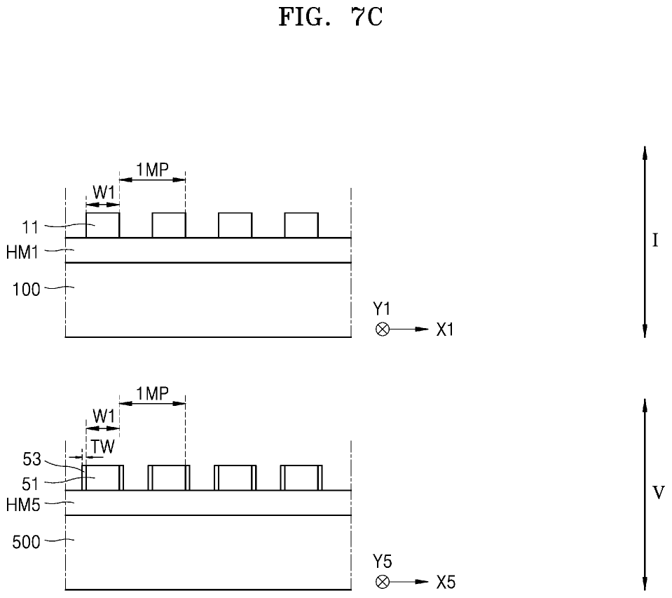

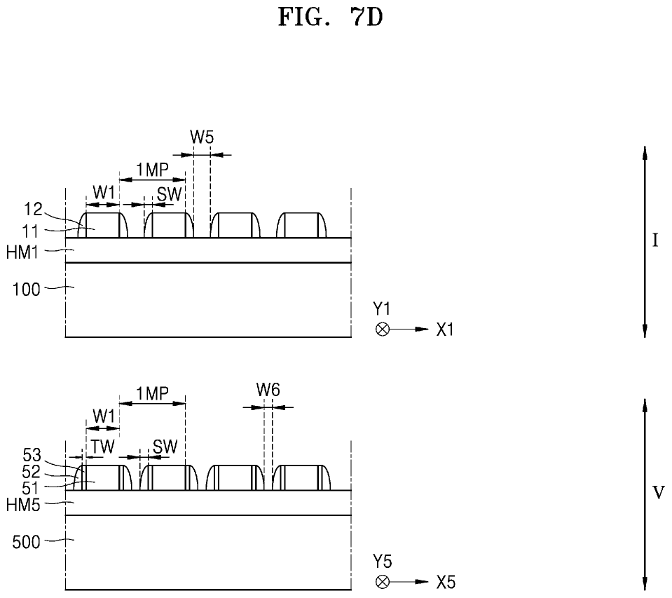

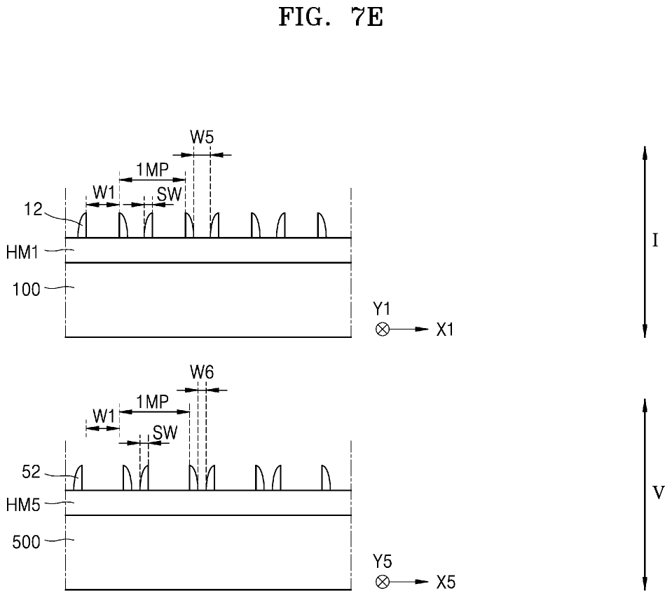

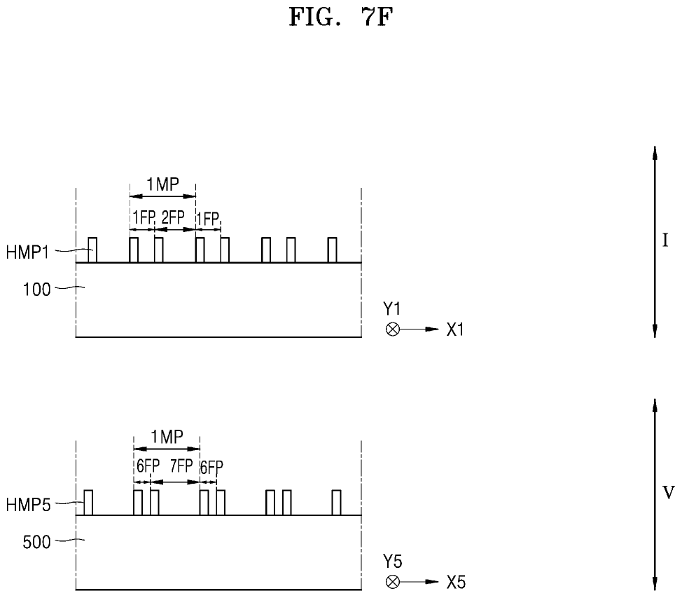

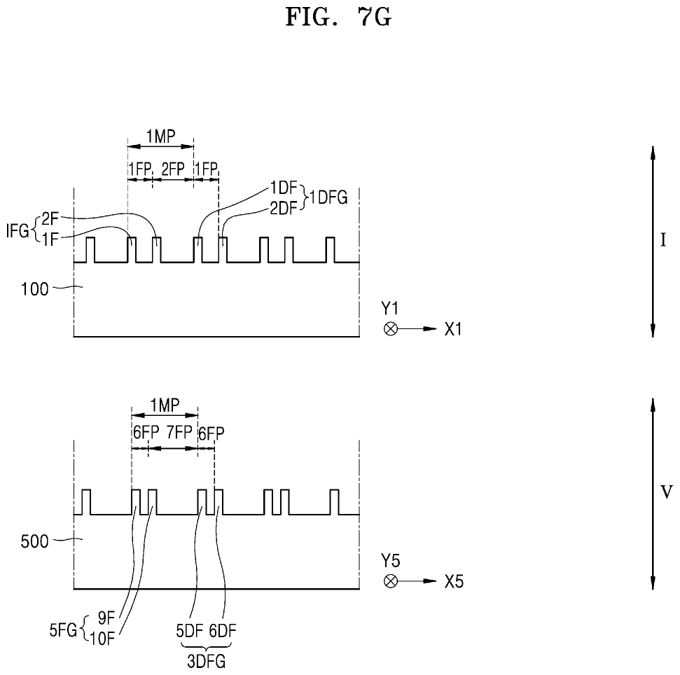

FIG. 6 is a conceptual diagram illustrating a method of manufacturing a semiconductor device, according to an embodiment of the present inventive concept. FIGS. 7A to 7G are diagrams of intermediate stages in the method of FIG. 6. Differences from FIGS. 1 to 2G are mainly described below, and redundant descriptions may be omitted or briefly discussed.

Referring to FIGS. 6 and 7A, a substrate having the first region I and a fifth region V may be provided. A fifth hardmask film HM5 and a fifth sacrificial film 51L may be sequentially formed on a substrate 500 in the fifth region V, and fifth photoresist patterns 50 having the first mandrel pitch 1MP may be formed. The fifth photoresist patterns 50 may be arranged in the first direction X1 in the fifth region V and may extend in the second direction Y1. In some embodiments of the present inventive concept, the first mandrel pitch 1MP may be at least about 76 nm.

In some embodiments of the present inventive concept, the width W1 in the first direction X1 of each first photoresist pattern 10 may be the same as the width W1 in a ninth direction X5 of each fifth photoresist pattern 50. In other words, a distance between two adjacent first photoresist patterns 10 may be the same as a distance between two adjacent fifth photoresist patterns 50. However, this is just an example, and the width W1 of the fifth photoresist pattern 50 may vary with occasions.

Referring to FIGS. 6 and 7B, a first mandrel pattern 11 may be formed by transferring a first photoresist pattern 10, and a fifth mandrel pattern 51 may be formed by transferring a fifth photoresist pattern 50. For example, the first mandrel pattern 11 may be formed by etching the first sacrificial film 11L by using the first photoresist pattern 10 on the substrate 100 in the first region I as a mask. The fifth mandrel pattern 51 may be formed by etching the fifth sacrificial film 51L by using the fifth photoresist pattern 50 on the substrate 500 in the fifth region V as a mask.

In some embodiments of the present inventive concept, fifth mandrel patterns 51 may be arranged in the ninth direction X5 and extend in a tenth direction Y5 in the fifth region V.

Subsequently, on the substrate 500 in the fifth region V, a sub spacer film 53L may be formed along the top surface and side surfaces of each fifth mandrel pattern 51 and the top surface of the fifth hardmask film HM5. The thickness of the sub spacer film 53L may be less than the thickness of a fifth spacer film, which is subsequently formed.

Referring to FIGS. 6 and 7C, on the substrate 500 in the fifth region V, a sub spacer 53 may be formed by anisotropically etching the sub spacer film 53L. The sub spacer 53 may be formed on each of both side walls of the fifth mandrel pattern 51.

Referring to FIGS. 6 and 7D, the first spacer 12 may be formed on a side wall of the first mandrel pattern 11 on the substrate 100 in the first region I, and a fifth spacer 52 may be formed on a side wall of the fifth mandrel pattern 51 on the substrate 500 in the fifth region V. In some embodiments of the present inventive concept, the fifth spacer 52 may be formed on the sub spacer 53 that is formed on each of both side walls of the fifth mandrel pattern 51.

In some embodiments of the present inventive concept, a width SW in the first direction X1 of the first spacer 12 may be the same as a width SW in the ninth direction X5 of the fifth spacer 52. However, this is just an example, and the width SW in the ninth direction X5 of the fifth spacer 52 may vary with occasions.

In some embodiments of the present inventive concept, a width TW in the ninth direction X5 of the sub spacer 53 may be less than the width SW in the ninth direction X5 of the fifth spacer 52.

In some embodiments of the present inventive concept, the sub spacer 53 may include at least one of silicon oxide, silicon nitride, silicon oxynitride, and a combination thereof. In some embodiments of the present inventive concept, the sub spacer 53 may include a material having the same etch selectivity as that of the fifth spacer 52. For example, when the fifth spacer 52 includes silicon oxide, the sub spacer 53 may include silicon nitride, silicon oxynitride, or a carbon-containing material, such as an ACL or an SOH.

In some embodiments of the present inventive concept, when the sub spacer 53 is formed on each of both side walls of the fifth mandrel pattern 51 and the fifth spacer 52 is formed on the sub spacer 53, the distance between two adjacent fifth spacers 52 having no fifth mandrel pattern 51 therebetween may decrease. In other words, a distance W6 between two adjacent fifth spacers 52 having no fifth mandrel pattern 51 therebetween may be less than a distance W5 between two adjacent first spacers 12 having no first mandrel pattern 11 therebetween.

Referring to FIGS. 6 and 7E, the first mandrel pattern 11 may be removed from the substrate 100 in the first region I, and the sub spacer 53 and the fifth mandrel pattern 51 may be removed from the substrate 500 in the fifth region V. The first spacer 12 may include a material having an etch selectivity with respect to the first mandrel pattern 11 and thus might not be removed when the first mandrel pattern 11 is removed. The fifth spacer 52 may include a material having an etch selectivity with respect to the sub spacer 53 and the fifth mandrel pattern 51 and thus might not be removed when the sub spacer 53 and the fifth mandrel pattern 51 are removed.

Referring to FIGS. 6 and 7F, a first hardmask pattern HMP1 and a fifth hardmask pattern HMP5 may be formed by using the first spacer 12 and the fifth spacer 52 as etch masks.

For example, the first hardmask film HM1 may be etched by using the first spacer 12 as an etch mask on the substrate 100 in the first region I. Subsequently, the first spacer 12 may be removed.

The fifth hardmask film HM5 may be etched by using the fifth spacer 52 as an etch mask on the substrate 500 in the fifth region V. In other words, the fifth hardmask pattern HMP5 may result from a transfer of the fifth spacer 52. Subsequently, the fifth spacer 52 may be removed.

Referring to FIGS. 6 and 7G, the substrates 100 and 500 may be patterned by using first hardmask patterns HMP1 and fifth hardmask patterns HMP5 as etch masks. Accordingly, a plurality of fins may be formed on the substrates 100 and 500.

For example, the first fin group 1FG and the first dummy fin group 1DFG, which are adjacent to each other in the first direction X1, may be formed by patterning the substrate 100 in the first region I by using the first hardmask patterns HMP1 as etch masks.

The first fin group 1FG may include the first fin 1F and the second fin 2F, which are arranged at the first fin pitch 1FP to be adjacent to each other in the first direction X1 and extend in the second direction Y1. The first dummy fin group 1DFG may include the first dummy fin 1DF and the second dummy fin 2DF, which are arranged at the first fin pitch 1FP to be adjacent to each other in the first direction X1 and extend in the second direction Y1.

In some embodiments of the present inventive concept, the second fin 2F and the first dummy fin 1DF adjacent to the second fin 2F may be arranged at the second fin pitch 2FP that is greater than the first fin pitch 1FP.

A fifth fin group 5FG and a third dummy fin group 3DFG, which are adjacent to each other in the ninth direction X5, may be formed by patterning the substrate 500 in the fifth region V by using the fifth hardmask patterns HMP5 as etch masks.

The fifth fin group 5FG may include a ninth fin 9F and a tenth fin 10F, which are arranged at a sixth fin pitch 6FP that is less than the first fin pitch 1FP, are adjacent to each other in the ninth direction X5, and extend in the tenth direction Y5. The third dummy fin group 3DFG may include a fifth dummy fin 5DF and a sixth dummy fin 6DF, which are arranged at the sixth fin pitch 6FP to be adjacent to each other in the ninth direction X5 and extend in the tenth direction Y5.

In some embodiments of the present inventive concept, the tenth fin 10F and the fifth dummy fin 5DF adjacent to the tenth fin 10F may be arranged at a seventh fin pitch 7FP that is greater than the second fin pitch 2FP.

The sixth fin pitch 6FP may be less than the first fin pitch 1FP that is less than about 38 nm. For example, when the first fin pitch 1FP is at least about 26 nm and less than about 38 nm, the sixth fin pitch 6FP may be less than about 26 nm. For example, when the first fin pitch 1FP is at least about 30 nm and less than about 38 nm, the sixth fin pitch 6FP may be less than about 30 nm. For example, when the first fin pitch 1FP is at least about 34 nm and less than about 38 nm, the sixth fin pitch 6FP may be less than about 34 nm. For example, the sixth fin pitch 6FP may be at least about 26 nm and less than about 34 nm.

Although it is illustrated in FIG. 6 that the first spacer 12 in the first region I and the fifth spacer 52 in the fifth region V have the same width SW, this is just for convenience of comparison. The width of the first spacer 12 may be different from the width of the fifth spacer 52.

A semiconductor device including the ninth fin 9F and the tenth fin 10F, which are arranged at the sixth fin pitch 6FP that is less than the first fin pitch 1FP, may be manufactured by the method illustrated in FIGS. 6 to 7G.

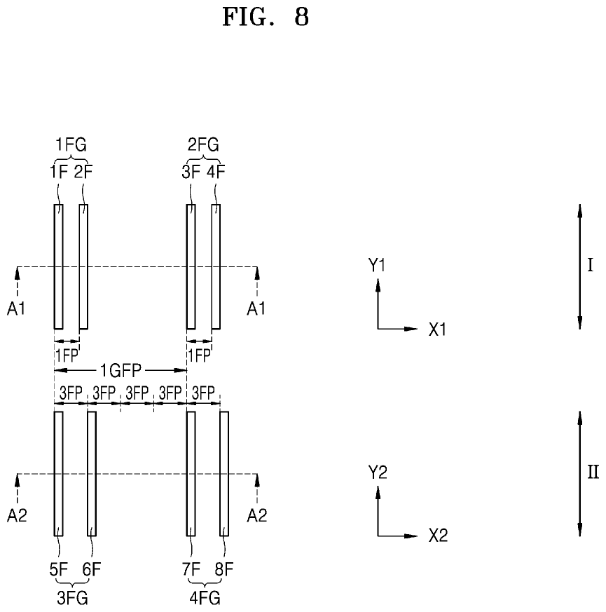

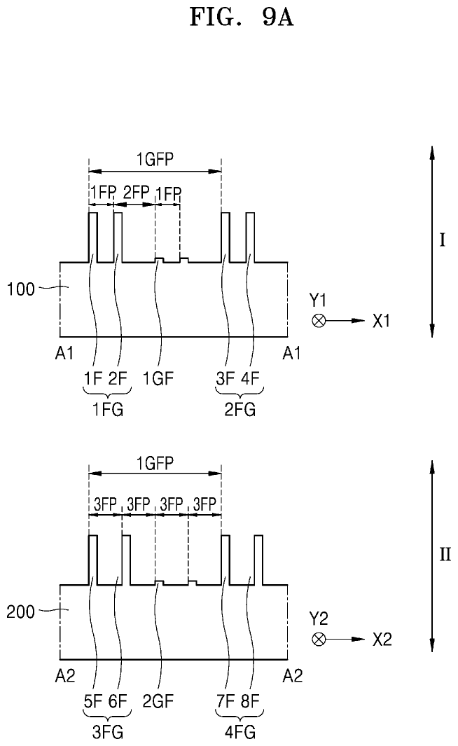

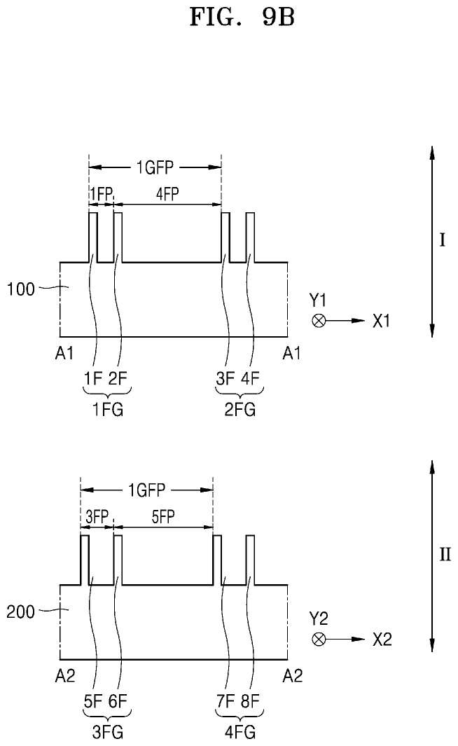

FIG. 8 is a layout diagram illustrating some components of a semiconductor device manufactured by a method of manufacturing a semiconductor device, according to an embodiment of the present inventive concept. For example, FIG. 8 is a layout diagram illustrating a fin-type active region of a semiconductor device manufactured by a method of manufacturing a semiconductor device, according to an embodiment of the present inventive concept. FIGS. 9A and 9B show cross-sectional views respectively taken along line A1-A1 and line A2-A2 in FIG. 8. For example, FIG. 9A shows cross-sectional views illustrating a substrate and a fin-type active region of a semiconductor device manufactured by the method described with reference to FIGS. 1 to 2G. FIG. 9B shows cross-sectional views illustrating a substrate and a fin-type active region of a semiconductor device manufactured by the method described with reference to FIG. 5.

Referring to FIGS. 8 and 9A, a fin-type active region including a plurality of fins may be disposed on the substrate 100 in the first region I. For example, the first fin 1F, the second fin 2F, the third fin 3F, and the fourth fin 4F may be spaced apart from each other in the first direction X1 and may extend in the second direction Y1. The first fin 1F and the second fin 2F may be arranged at the first fin pitch 1FP, and the third fin 3F and the fourth fin 4F may be arranged at the first fin pitch 1FP. The first ghost fins 1GF may be formed between the first fin group 1FG and the second fin group 2FG as traces left after the first and second dummy fins 1DF and 2DF (in FIGS. 1 to 2G) are removed. The second fin 2F and a first ghost fin 1GF adjacent to the second fin 2F may be arranged at the second fin pitch 2FP that is greater than the first fin pitch 1FP, and a first ghost fin 1GF and the third fin 3F adjacent to the first ghost fin 1GF may be arranged at the second fin pitch 2FP. The second fin pitch 2FP may be greater than the first fin pitch 1FP and less than about twice the first fin pitch 1FP.

Referring to FIGS. 8 and 9A, a fin-type active region including a plurality of fins may be disposed on the substrate 200 in the second region II. For example, the fifth fin 5F, the sixth fin 6F, the seventh fin 7F, and the eighth fin 8F may be spaced apart from each other in the third direction X2 and may extend in the fourth direction Y2. The fifth fin 5F and the sixth fin 6F may be arranged at the third fin pitch 3FP, and the seventh fin 7F and the eighth fin 8F may be arranged at the third fin pitch 3FP. The second ghost fins 2GF may be formed between the third fin group 3FG and the fourth fin group 4FG as traces left after the third and fourth dummy fins 3DF and 4DF (in FIGS. 1 to 2G) are removed. The sixth fin 6F and a second ghost fin 2GF adjacent to the sixth fin 6F may be arranged at the third fin pitch 3FP, and a second ghost fin 2GF and the seventh fin 7F adjacent to the second ghost fin 2GF may be arranged at the third fin pitch 3FP. The third fin pitch 3FP may be greater than the first fin pitch 1FP and less than the second fin pitch 2FP.

Detailed descriptions of the first to eighth fins 1F to 8F, the first to fourth fin groups 1FG to 4FG, the first ghost fins 1GF, the second ghost fins 2GF, and the first to third fin pitches 1FP to 3FP are the same as those given above with reference to FIGS. 1 to 2G.

Referring to FIGS. 8 and 9B, a fin-type active region including a plurality of fins may be formed on the substrate 100 in the first region I. For example, the first fin 1F, the second fin 2F, the third fin 3F, and the fourth fin 4F may be spaced apart from each other in the first direction X1 and may extend in the second direction Y1. Unlike FIG. 9A, the first ghost fins 1GF might not be formed on the substrate 100 in the first region I. The first fin 1F and the second fin 2F may be arranged at the first fin pitch 1FP, and the third fin 3F and the fourth fin 4F may be arranged at the first fin pitch 1FP. The second fin 2F and the third fin 3F may be arranged at the fourth fin pitch 4FP that is greater than about three times the first fin pitch 1FP.

Referring to FIGS. 8 and 9B, a fin-type active region including a plurality of fins may be formed on the substrate 200 in the second region II. For example, the fifth fin 5F, the sixth fin 6F, the seventh fin 7F, and the eighth fin 8F may be spaced apart from each other in the third direction X2 and may extend in the fourth direction Y2. Unlike FIG. 9A, the second ghost fins 2GF might not be formed on the substrate 200 in the second region II. The fifth fin 5F and the sixth fin 6F may be arranged at the third fin pitch 3FP, and the seventh fin 7F and the eighth fin 8F may be arranged at the third fin pitch 3FP. The sixth fin 6F and the seventh fin 7F may be arranged at the fifth fin pitch 5FP that is about three times the third fin pitch 3FP.

Detailed descriptions of the first to eighth fins 1F to 8F, the first to fourth fin groups 1FG to 4FG, the first fin pitch 1FP, and the third to fifth fin pitches 3FP to 5FP are the same as those given above with reference to FIG. 5.

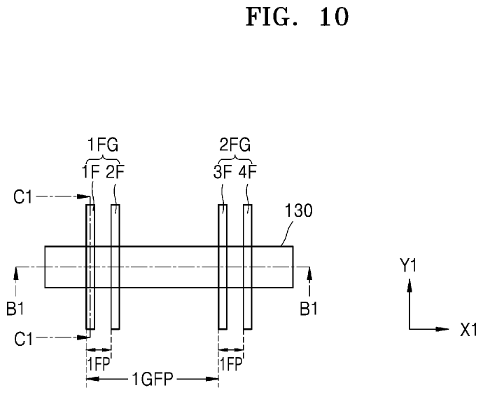

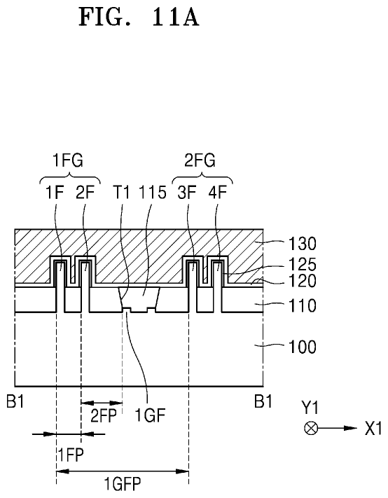

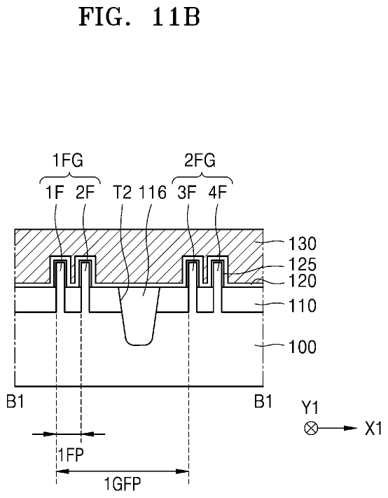

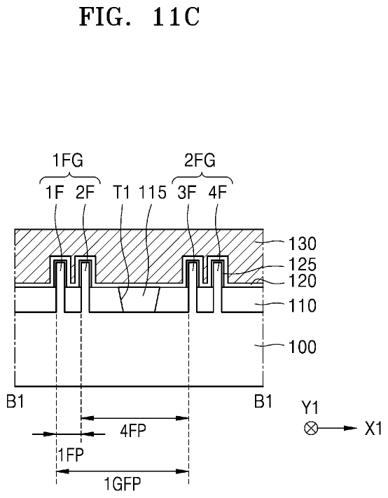

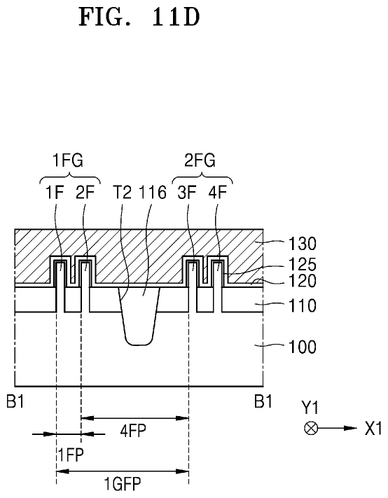

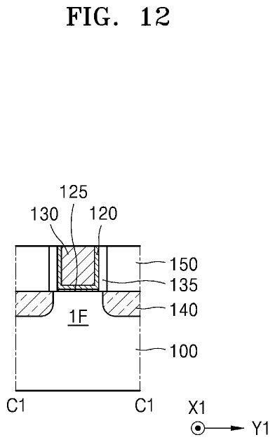

FIG. 10 is a layout diagram illustrating some components of a semiconductor device manufactured by a method of manufacturing a semiconductor device, according to an embodiment of the present inventive concept. For example, FIG. 10 is a layout diagram illustrating a plurality of fins and a gate electrode of a semiconductor device manufactured by a method of manufacturing a semiconductor device, according to an embodiment of the present inventive concept FIGS. 11A to 11D are cross-sectional views taken along line B1-B1 in FIG. 10. In detail, FIGS. 11A and 11B are cross-sectional views illustrating a semiconductor device manufactured by the method described with reference to FIGS. 1 to 2G FIGS. 11C and 11D are cross-sectional views illustrating a semiconductor device manufactured by the method described with reference to FIG. 5. FIG. 12 is a cross-sectional view taken along line C1-C1 in FIG. 10.

Referring to FIGS. 10 to 12, a semiconductor device manufactured by a method of manufacturing a semiconductor device, according to an embodiment of the present inventive concept, may include a first gate electrode 130, a first gate dielectric film 120, a first interface film 125, a first gate spacer 135, a first source/drain region 140, and a first interlayer insulating film 150.

In some embodiments of the present inventive concept, the first gate electrode 130 may be formed on the first to fourth fins 1F to 4F. The first gate electrode 130 may extend in a direction that crosses the direction in which the first to fourth fins 1F to 4F extend. For example, the first gate electrode 130 may extend in the first direction X1 and the first to fourth fins 1F to 4F may extend in the second direction Y1. The first gate electrode 130 may include a conductive material.

In some embodiments of the present inventive concept, the first gate dielectric film 120 may be disposed between the first gate electrode 130 and the first to fourth fins 1F to 4F. For example, the first gate dielectric film 120 may extend along the side walls and top surface of each of the first to fourth fins 1F to 4F. In some embodiments of the present inventive concept, the first gate dielectric film 120 may also be disposed between the first field insulating film 110 and the first gate electrode 130. For example, the first gate dielectric film 120 may further extend along the top surface of the first field insulating film 110.

In some embodiments of the present inventive concept, the first gate dielectric film 120 may include at least one of silicon oxide, silicon oxynitride, silicon nitride, and a high-k material having a higher dielectric constant than that of silicon oxide.

In some embodiments of the present inventive concept, the first interface film 125 may be disposed between each of the first to fourth fins 1F to 4F and the first gate dielectric film 120. In some embodiments of the present inventive concept, the first gate spacer 135 may extend along each of both side walls of the first gate electrode 130.

In some embodiments of the present inventive concept, the first source/drain region 140 may be formed in each of the first to fourth fins 1F to 4F. In some embodiments of the present inventive concept, the first interlayer insulating film 150 may be formed on the substrate 100 in the first region I The first interlayer insulating film 150 may cover the first field insulating film 110, the first source/drain region 140, and the first gate spacer 135.

In some embodiments of the present inventive concept, the semiconductor device described with reference to FIGS. 10 to 12 may correspond to a fin field-effect transistor (FinFET).

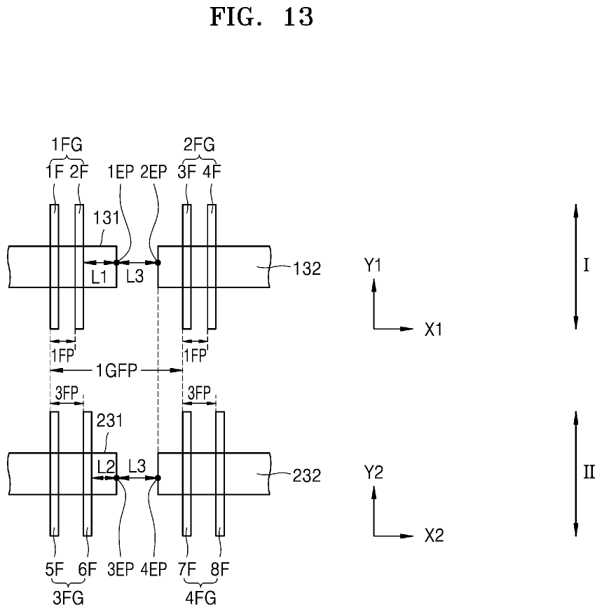

FIG. 13 is a layout diagram illustrating some components of a semiconductor device manufactured by a method of manufacturing a semiconductor device, according to an embodiment of the present inventive concept. In detail, FIG. 13 shows a stage following the method illustrated in FIGS. 1 to 2G.

Referring to FIG. 13, the method of manufacturing a semiconductor device, according to an embodiment of the present inventive concept, may further include forming a first sub gate electrode 131, which extends on the first fin group 1FG in the first direction X1, and a second sub gate electrode 132, which extends on the second fin group 2FG in the first direction X1, on the substrate 100 in the first region I.

The first sub gate electrode 131 may include a first end portion 1EP between the first fin group 1FG and the second fin group 2FG. For example, the first sub gate electrode 131 may have the first end portion 1EP between the second fin 2F and the third fin 3F. The second sub gate electrode 132 may include a second end portion 2EP between the first fin group 1FG and the second fin group 2FG. For example, the second sub gate electrode 132 may have the second end portion 2EP between the second fin 2F and the third fin 3F.

The method of manufacturing a semiconductor device, according to embodiments of the present inventive concept, may further include forming a third sub gate electrode 231, which extends on the third fin group 3FG in the third direction X2, and a fourth sub gate electrode 232, which extends on the fourth fin group 4FG in the third direction X2, on the substrate 200 in the second region II.

The third sub gate electrode 231 may include a third end portion 3EP between the third fin group 3FG and the fourth fin group 4FG. For example, the third sub gate electrode 231 may have the third end portion 3EP between the sixth fin 6F and the seventh fin 7F. The fourth sub gate electrode 232 may include a fourth end portion 4EP between the third fin group 3FG and the fourth fin group 4FG. For example, the fourth sub gate electrode 232 may have the fourth end portion 4EP between the sixth fin 6F and the seventh fin 7F.

In some embodiments of the present inventive concept, a first distance L1 between the first end portion 1EP and the first fin group 1FG may be greater than a second distance L2 between the third end portion 3EP and the third fin group 3FG. For example, the first distance L1 between the first end portion EP and the second fin 2F may be greater than the second distance L2 between the third end portion 3EP and the sixth fin 6F.

A third distance L3 between the first sub gate electrode 131 and the second sub gate electrode 132 may be the same as a third distance 13 between the third sub gate electrode 231 and the fourth sub gate electrode 232. Because the first fin pitch 1FP between the first fin 1F and the second fin 2F in the first fin group 1FG is less than the third fin pitch 3FP between the fifth fin 5F and the sixth fin 6F in the third fin group 3FG, there may be a difference between the first distance L1 and the second distance L2.

In other words, because of the first fin 1F and the second fin 2F, which are arranged at the first fin pitch 1FP that is less than the third fin pitch 3FP, there may be provided a method of manufacturing a semiconductor device according to an embodiment of the present inventive concept and a semiconductor device manufactured by the method according to an embodiment of the present inventive concept. In the method of manufacturing a semiconductor device according to an embodiment of the present inventive concept, the first distance L1, e.g., in a gate extension direction, that is between the first end portion 1EP and the second fin 2F is longer than the second distance L2 that is between the third end portion 3EP and the sixth fin 6F. Accordingly, a method of manufacturing a semiconductor device having increased reliability and a semiconductor device manufactured by the method may be provided.

While the present inventive concept has been described with reference to example embodiments thereof, it will be understood by those of ordinary skill in the art that various changes in form and details may be made thereto without departing from the spirit and scope of the present inventive concept.

What is claimed is:

1. A method of manufacturing a semiconductor device, the method comprising:
forming a plurality of first mandrel patterns at a first mandrel pitch on a substrate;
forming a plurality of first spacers on opposing side walls of each of the plurality of first mandrel patterns;
forming a first fin group and a first dummy fin group by patterning the substrate by using the plurality of first spacers, wherein the first fin group is adjacent to the first dummy fin group in a first direction; and
removing the first dummy fin group,
wherein the first fin group includes a first fin and a second fin adjacent to each other and arranged at a first fin pitch in the first direction, wherein the first fin and the second fin extend in a second direction that crosses the first direction,
the first dummy fin group includes a first dummy fin and a second dummy fin adjacent to each other and arranged at the first fin pitch in the first direction, wherein the first dummy fin and the second dummy fin extend in the second direction, and
the second fin and the first dummy fin, which is adjacent to the second fin, are arranged at a second fin pitch that is greater than the first fin pitch.

2. The method of claim 1, wherein the forming the first fin group and the first dummy fin group includes forming a second fin group that is separated from the first fin group by the first dummy fin group,
wherein the method further comprises, after the removing of the first dummy fin group;
forming a first field insulating film between the first fin group and the second fin group;
forming a first trench by etching a portion of the first field insulating film between the first fin group and the second fin group; and
forming a second field insulating film in the first trench,
wherein the first field insulating film has a different stress state than that of the second field insulating film.

3. The method of claim 2, wherein the forming of the first trench further includes etching a portion of the substrate, wherein a lower surface of the first trench is at a lower vertical level than that of a lower surface of the first field insulating film.

4. The method of claim 1, wherein the second fin pitch is greater than the first fin pitch and less than twice the first fin pitch.

5. The method of claim 1, wherein the forming the first fin group and the first dummy fin group includes forming a second fin group that is separated from the first fin group by the first dummy fin group, and
the first fin group and the second fin group are arranged at a first fin group pitch that is twice the first mandrel pitch.

6. The method of claim 5, wherein the first fin group pitch is greater than four times the first fin pitch.

7. The method of claim 1, wherein the first fin group and the first dummy fin group are arranged at the first mandrel pitch.

8. The method of claim 1, further comprising forming a second spacer covering the plurality of first mandrel patterns before the forming the plurality of first spacers,
wherein the forming the plurality of first spacers includes forming a plurality of first spacers separated from each of the plurality of first mandrel patterns by the second spacer, and
the second spacer has an etch selectivity with respect to the plurality of first spacers.

9. The method of claim 1, wherein the first mandrel pitch is at least about 76 nm, and
the first fin pitch is less than half the first mandrel pitch.

10. A method of manufacturing a semiconductor device, the method comprising:
forming a plurality of first mandrel patterns at a first mandrel pitch on a substrate;
forming a first spacer on each of a plurality of side walls of each of the plurality of first mandrel patterns; and
forming a first fin group and a second fin group by patterning the substrate by using the first spacer, wherein the first fin group is adjacent to the second fin group in a first direction,
wherein the first fin group includes a first fin and a second fin adjacent to each other and arranged at a first fin pitch in the first direction, wherein the first fin and the second fin extend in a second direction that crosses the first direction,
the second fin group includes a third fin and a fourth fin adjacent to each other and arranged at the first fin pitch in the first direction, wherein the third fin and the fourth fin extend in the second direction, and
the second fin and the third fin, which is adjacent to the second fin, are arranged at a second fin pitch that is greater than three times the first fin pitch.

11. The method of claim 10, further comprising:
forming a first field insulating film between the first fin group and the second fin group;
forming a first trench by etching a portion of the first field insulating film between the first fin group and the second fin group; and
filling the first trench with a second field insulating film,
wherein the first field insulating film has a different stress state than that of the second field insulating film.

12. The method of claim 11, wherein the forming of the first trench further includes etching a portion of the substrate, wherein a lower surface of the first trench is at a lower vertical level than that of a lower surface of the first field insulating film.

13. The method of claim 10, wherein the second fin pitch is less than five times the first fin pitch.

14. The method of claim 10, wherein the first mandrel pitch is greater than four times the first fin pitch, and
the first fin group and the second fin group are arranged at the first mandrel pitch.

15. A method of manufacturing a semiconductor device, the method comprising:
forming a plurality of first mandrel patterns at a first mandrel pitch in a first region of a substrate;
forming a plurality of second mandrel patterns at the first mandrel pitch in a second region of the substrate;
forming a plurality of first spacers on side walls of each of the plurality of first mandrel patterns;
forming a plurality of second spacers on side walls of each of the plurality of second mandrel patterns;
forming a plurality of first fin groups and a plurality of first dummy fin groups by patterning the first region of the substrate by using the plurality of first spacers, wherein the plurality of first fin groups are alternately arranged with the plurality of first dummy fin groups in a first direction;
forming a plurality of second fin groups and a plurality of second dummy fin groups by patterning the second region of the substrate by using the plurality of second spacers, wherein the plurality of second fin groups are alternately arranged with the plurality of second dummy fin groups in a second direction; and
removing the plurality of first dummy fin groups and the plurality of second dummy fin groups,
wherein each of the plurality of first fin groups includes a first fin and a second fin adjacent to each other and arranged at a first fin pitch in the first direction, wherein the first fin and the second fin extend in a third direction that crosses the first direction,
each of the plurality of first dummy fin groups includes a first dummy fin and a second dummy fin adjacent to each other and arranged at the first fin pitch in the first direction, wherein the first dummy fin and the second dummy fin extending in the third direction,
the second fin and the first dummy fin, which is adjacent to the second fin, are arranged at a second fin pitch that is greater than the first fin pitch,
each of the plurality of second fin groups includes a third fin and a fourth fin adjacent to each other and arranged at a third fin pitch in the second direction, wherein the third fin and the fourth fin extend in a fourth direction that crosses the second direction,
each of the plurality of second dummy fin groups includes a third dummy fin and a fourth dummy fin adjacent to each other and arranged at the third fin pitch in the second direction, wherein the third dummy fin and the fourth dummy fin extend in the fourth direction,
the fourth fin and the third dummy fin, which is adjacent to the fourth fin, are arranged at the third fin pitch,
the first fin pitch is less than the third fin pitch, and
the second fin pitch is greater than the third fin pitch.

16. The method of claim 15, wherein the second dummy fin and the first fin, which is adjacent to the second dummy fin, are arranged at the second fin pitch, and
the fourth dummy fin and the third fin, which is adjacent to the fourth dummy fin, are arranged at the third fin pitch.

17. The method of claim 15, wherein the second fin pitch is greater than the first fin pitch and less than twice the first fin pitch.

18. The method of claim 15, wherein the first fin pitch is greater than ⅔ of the third fin pitch and less than the third fin pitch, and
the second fin pitch is greater than the third fin pitch and less than 4/3 of the third fin pitch.

19. The method of claim 15, further comprising, after the removing of the plurality of first dummy fin groups and the plurality of second dummy fin groups:
forming a first field insulating film in the first region, wherein the first field insulating film at least partially surrounds a lower portion of each of the plurality of first fin groups;
forming a first trench by etching the first field insulating film that is between two adjacent first fin groups among the plurality of first fin groups; and
forming a second field insulating film in the first trench,
wherein the first field insulating film has a different stress state than that of the second field insulating film.

20. The method of claim 15, wherein the plurality of first fin groups include a first sub fin group and a second sub fin group adjacent to each other, and
the plurality of second fin groups include a third sub fin group and a fourth sub fin group adjacent to each other,
wherein the method further comprises:
forming a first gate electrode on the first sub fin group and extending in the first direction in the first region of the substrate, wherein the first gate electrode has a first end portion between the first sub fin group and the second sub fin group; and
forming a second gate electrode on the third sub fin group and extending in the second direction in the second region of the substrate, wherein the second gate electrode has a second end portion between the third sub fin group and the fourth sub fin group,
wherein a first distance, which is between the first end portion of the first gate electrode and the first sub fin group, is greater than a second distance, which is between the second end portion of the second gate electrode and the third sub fin group.
